(19) United States
(12) Patent Application Publication
(10) Pub. No.: US 2014/0119858 A1
(43) Pub. Date: May 1, 2014

(54) Semiconductor Device Manufacturing Line

(71) Applicant: SANDISK 3D LLC, MILPITAS, CA (US)

(72) Inventors: Atsuyoshi Koike, Tokyo (JP); Takayuki Wakabayashi, Tokyo (JP); Hideki Kishi, Tokyo (JP)

(73) Assignee: SANDISK 3D LLC, MILPITAS, CA (US)

(21) Appl. No.: 14/032,041

(22) Filed: Sep. 19, 2013

Related U.S. Application Data
(60) Provisional application No. 61/720,705, filed on Oct. 31, 2012.

(51) Int. Cl. H01L 21/677

(52) U.S. Cl. CPC H01L 21/67703
USPC 414/222.13

(57) ABSTRACT

A semiconductor device manufacturing line includes a process system that includes a plurality of process units of a single wafer process type, and a carrier system that carries wafers to the plurality of process units. The carrier system includes a plurality of carrier units each carrying one wafer from one of the process units to another process unit of a next process.

This application claims the benefit of U.S. Provisional Patent Application No. 61/720,705, entitled “Integrated Circuit Manufacturing,” filed on Oct. 31, 2012, which is hereby incorporated by reference in its entirety.

### BACKGROUND OF THE INVENTION

1. Field of the Invention

The present invention relates to a semiconductor device manufacturing line, and more specifically, to a semiconductor device manufacturing line for semiconductor device integrated circuits, etc.

2. Description of the Related Art

A semiconductor device manufacturing line includes multiple process devices performing processes, such as film deposition like sputtering and CVD (Chemical Vapor Deposition), exposure, etching, rinsing, and CMP (Chemical Mechanical Polishing) on wafers, and inspection thereon, and a carrier device that carries the wafers from a process device to another process device of the next process. In general, the process device includes multiple chambers therein to improve the throughput. The process device needing high vacuum for a process includes a load lock chamber that carries the wafers to the chamber in a high vacuum condition. Those process devices include an internal carrier mechanism that carries the wafers from the wafer entrance to the load lock chamber, from the load lock chamber to the process chamber, or from a process chamber to another process chamber. This allows the process devices to perform a certain process on the multiple wafers in a parallel manner, or to perform related processes sequentially.

In order to manufacture semiconductor devices, it is necessary to form minute transistors by performing various processes on a wafer, and to further form wirings thereon. The kinds of the processes are over dozens of kinds, and a semiconductor device can be manufactured through several hundred processes (see, for example, JP 2005-108883 A).

In recent years, in order to meet the demands for downsizing of the wiring pitch of a circuit and improvement of the quality, the requirement for each process (element process) becomes also strict. With respect to such a requirement, each chamber becomes highly functionable, and each device manufacturer advances the development of a device and a process. Since each device manufacturer attempts to optimize the arrangement of chambers and the way of delivering a wafer, etc., for each process device, the internal carrier mechanism of the process device typically differs for each device manufacturer (for each device).

It is necessary for a device manufacturer which manufactures a process device to individually develop an internal carrier mechanism together with the development of a chamber, and thus the burden for development is remarkable. Moreover, a semiconductor device manufacturing line needs to have both internal carrier mechanism in the process device and carrier device provided between the process devices, and thus multiple carrier mechanisms are present in such a line. Hence, the semiconductor device manufacturing line becomes complex as a whole.

It is an object of the present invention to provide a semiconductor device manufacturing line which facilitates an assembling of a manufacturing line with various chambers produced by different device manufacturers.

### SUMMARY OF THE INVENTION

A semiconductor device manufacturing line according to an aspect of the present invention includes: a process system comprising a plurality of process units of a single wafer process type; and a carrier system that carries wafers to the plurality of process units. The carrier system includes a plurality of carrier units each carrying one wafer from one of the process units to another process unit of a next process.

According to an aspect of the present invention, the semiconductor device manufacturing line employs a structure in which the carrier system delivers one wafer W to each process unit, and thus the carrier system can be commonly utilized. This enables a built-in of each process unit in the manufacturing line by simply connecting each process unit with the carrier system. Hence, the semiconductor device manufacturing line can be easily assembled using various process units of different device manufacturers.

### BRIEF DESCRIPTION OF THE DRAWINGS

FIG. 1 is a schematic diagram illustrating a whole structure of a semiconductor device manufacturing line according to an embodiment;

FIG. 2 is a vertical cross-sectional view illustrating a structure of a chamber;

FIG. 3 is a vertical cross-sectional view illustrating a structure of a simultaneous process unit;

FIG. 4A is a schematic diagram illustrating a structure of a carrier unit and is a front view thereof;

FIG. 4B is a schematic diagram illustrating the structure of the carrier unit, and is a cross-sectional view taken along a line A-A in FIG. 4A;

FIG. 5 is a schematic diagram illustrating a structure of an elevating unit;

FIG. 6A is an exemplary diagram illustrating a use condition in which the carrier unit stops ahead of a chamber;

FIG. 6B is an exemplary diagram illustrating a use condition in which the carrier unit turns with respect to the chamber;

FIG. 6C is an exemplary diagram illustrating a use condition in which the carrier unit is coupled with the chamber;

FIG. 7 is a front view illustrating a condition in which the elevating unit lifts up the carrier unit;

FIG. 8A is a partial vertical cross-sectional view illustrating a use condition in which the elevating unit turns to direct the carrier unit toward the chamber;

FIG. 8B is a partial vertical cross-sectional view illustrating a use condition in which the elevating unit causes the carrier unit to move forward toward the chamber;

FIG. 9A is a vertical cross-sectional view illustrating a use condition in which the carrier unit faces the chamber;

FIG. 9B is a vertical cross-sectional view illustrating a use condition in which the carrier unit is coupled with the chamber;

FIG. 9C is a vertical cross-sectional view illustrating a use condition in which the door of the carrier unit is drawn to the interior of the chamber; and

FIG. 9D is a vertical cross-sectional view illustrating a use condition in which the opening of the carrier unit, the opening of the chamber for wafers and the opening thereof for arms are opened.

### DETAILED DESCRIPTION OF THE PREFERRED EMBODIMENTS

An explanation will be given of an embodiment of the present invention in detail with reference to the accompanying drawings.

### Entire Structure

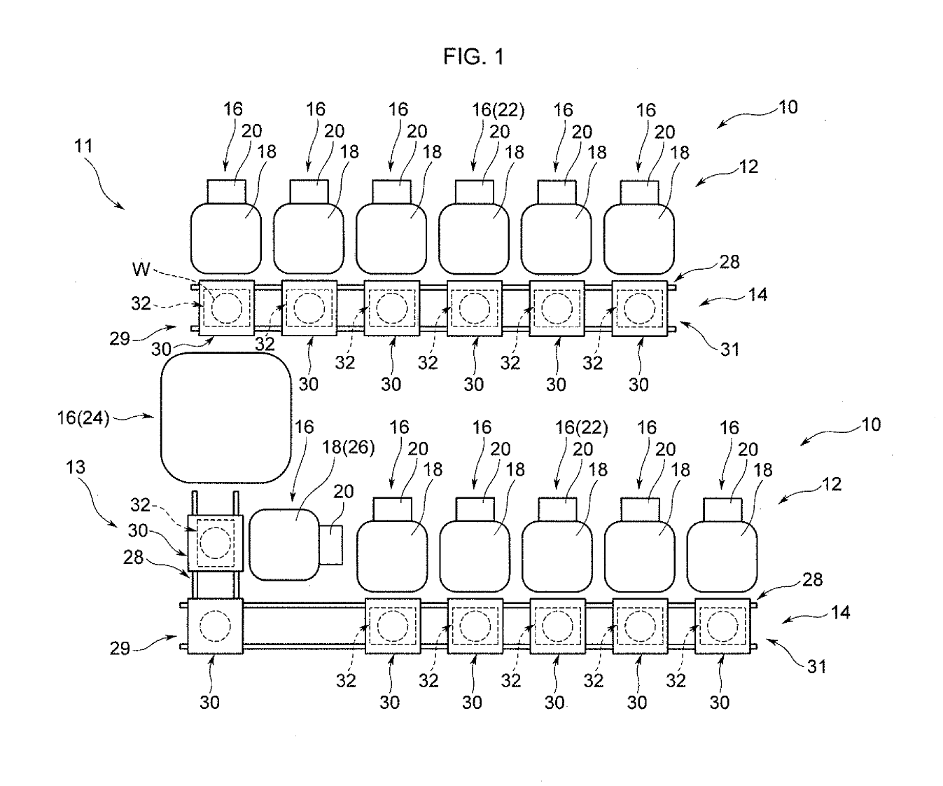

A semiconductor device manufacturing line 10 illustrated in FIG. 1 includes a process system 12, a carrier system 14, and a central control device (unillustrated), and is installed in a clean room (unillustrated). The central control device comprehensively controls the process system 12 and the carrier system 14. The semiconductor device manufacturing line 10 causes the carrier system 14 to repeatedly supply wafers W to the process system 12 at a predetermined timing, to receive the processed wafers W, and to carry the wafers W to the next process, thereby eventually manufacturing semiconductor devices. In this figure, a first manufacturing line 11 and a second manufacturing line 13 are illustrated as the semiconductor device manufacturing line 10. Basically, the process system 12 processes the wafer W carried by either one carrier system 14 that is the first manufacturing line 11 or the second manufacturing line 13.

What the central control device mainly does are monitoring of the operation status of the process system 12 and that of the carrier system 14, scheduling of carrying the wafers W, timing control of a carrying instruction to the carrier system 14, and management of the carrying status and carrying record.

The process system 12 includes multiple process units 16. The respective process units 16 are arranged in a manner lined up side by side. The process unit 16 includes at least one chamber 18. Examples of the chamber 18 are all process chambers adopted to a typical semiconductor device manufacturing line, such as for film formation like sputtering or CVD, exposure, etching, rinsing, and CMP, an inspection chamber, a stand-by chamber 26, a pressure changing chamber, and a preparation chamber.

The carrier system 14 includes a carrying path 28 provided along the process units 16, a carrier unit 30 that autonomously travels over the carrying path 28, and an elevating unit 32 provided at each process unit 16. The carrying path 28 is formed by two parallel rails disposed horizontally. The carrier unit 30 is formed in such a manner as to travel in a one-way manner toward an unload port 31 after being loaded in a load port 29.

According to this embodiment, the carrying paths 28 of the first manufacturing line 11 and the second manufacturing line 13 are disposed in a parallel manner with each other. Moreover, the first and second manufacturing lines 11 and 13 are each formed by a set of multiple process units 16 lined up toward the one side of the one carrying path 28, i.e., toward the left in the carrying direction in FIG. 1.

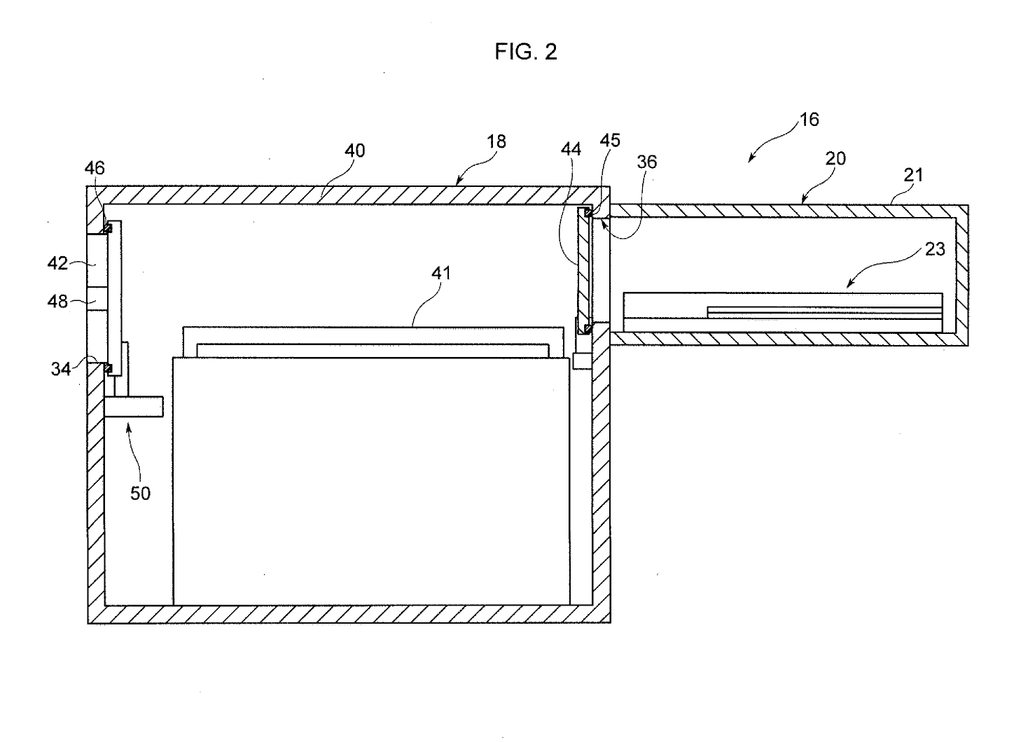

As illustrated in FIG. 2, the chamber 18 includes a main body 40 and an arm unit 20 provided to the main body 40. The main body 40 is an air-tightly closed container with an internal space, and has a wafer opening 34 and an arm opening 36. The chamber 18 is disposed with the wafer opening 34 being directed toward the carrying path 28. A base 41 that holds the wafer W is provided in the main body 40.

A wafer door 42 is provided to the wafer opening 34 in freely openable/closable manner. The wafer door 42 includes a seal 46, a lock canceling unit 48, and a suction unit (unillustrated), and is connected with a door moving unit 50 provided at the main body 40. The wafer door 42 air-tightly closes the wafer opening 34 when fastened with the seal 46 being held between the wafer door 42 and the main body 40. The door moving unit 50 retracts the wafer door 42 in the main body 40, and moves such a door downwardly.

An arm door 44 is provided to the arm opening 36 in freely openable/closable manner. The arm door 44 includes a seal 45. The arm door 44 air-tightly closes the arm opening 36 when fastened with the seal 45 being held between the arm door 44 and the main body 40. The arm opening 36 is connected with the arm unit 20.

The arm unit 20 includes an arm room 21 and an arm 23 retained in the arm room 21. The arm 23 is formed so as to be extensible, and allows a tip of the arm 23 to be out of the main body 40 through the interior of the main body 40 and the wafer opening 34 from the arm opening 36 when elongated.

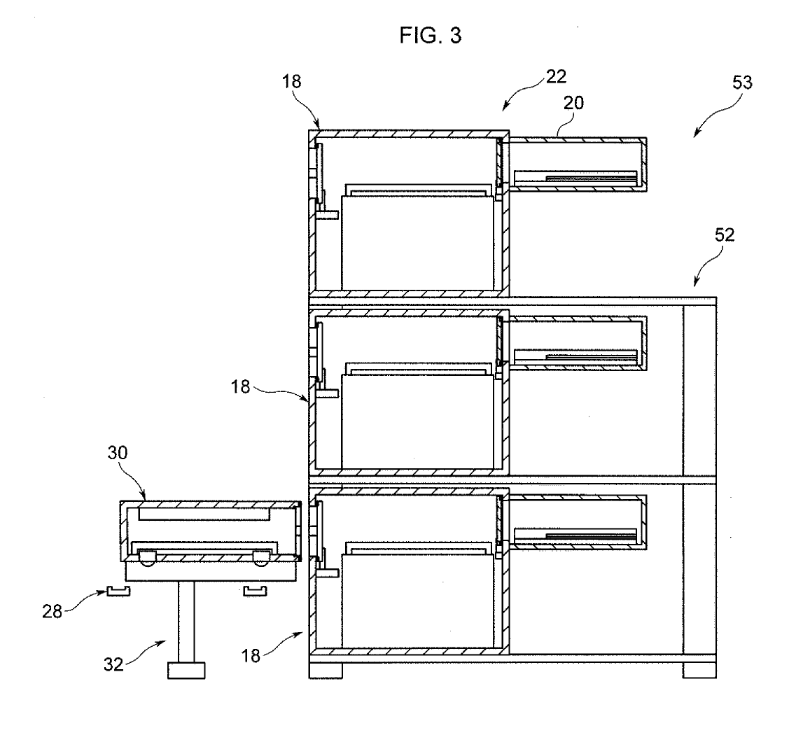

The process unit 16 constructing the process system 12 includes a simultaneous process unit 22 having the multiple chambers 18, in the example case illustrated in FIG. 3, three chambers 18 stacked on one another. The simultaneous process unit 22 includes a rack 52, and the three chambers 18 are stacked in the vertical direction. The simultaneous process unit 22 includes the chambers 18 each having a small throughput. The term throughput means the number of wafers W that can be processed per a unit time. In the simultaneous process unit 22, the elevating unit 32 lifts up the carrier unit 30 to a position of the predetermined chamber 18 to transport the wafer W.

The rack 52 is formed so as to allow the chamber 18 to retract from a position where the wafer W can be delivered with respect to the carrier unit 30 to a maintenance position 53. Accordingly, when the chamber 18 becomes defective, it can be individually subjected to a maintenance work by causing the chamber 18 to be retracted to the maintenance position 53. Hence, the process unit 16 can continue the process on the wafer W through another chamber 18 while allowing the defective chamber 18 to be subjected to a maintenance work by blocking off the position where the wafer W can be delivered and the maintenance position 53 so as to prevent gases from flowing therebetween.

The process units 16 constructing the process system 12 include a high-throughput process unit 24 (see FIG. 1). The high-throughput process unit 24 is the chamber 18 that has the larger number of wafers W which can be processed per a unit time. The high-throughput process unit 24 includes a wafer opening (unillustrated) for delivering up the wafer W and is provided between the first manufacturing line 11 and the second manufacturing line 13. In general, one wafer opening is provided for each manufacturing line. A transfer unit (unillustrated) is provided between the wafer opening and the first and second manufacturing lines 11 and 13. The transfer unit delivers up the wafer W with respect to the first manufacturing line 11 and the second manufacturing line 13. The transfer unit can be formed likewise the carrier system.

The high-throughput process unit 24 receives the wafer W supplied from both first and second manufacturing lines 11 and 13 through the respective wafer openings, processes such a wafer, and delivers the processed wafer W to the first and second manufacturing lines 11 and 13 through the respective wafer openings.

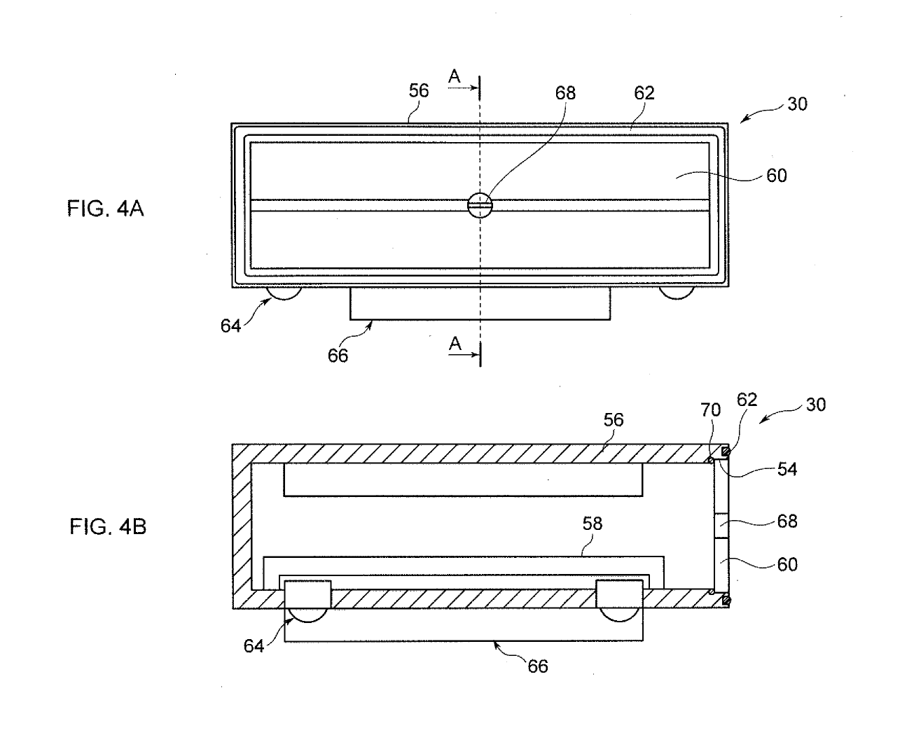

As illustrated in FIG. 4, the carrier unit 30 includes a main body 56, wheels 64, and a control room 66. The main body 56 is an air-tightly closed container with an internal space, and has an opening 54. A base 58 on which the wafer W is loaded is provided in the main body 56.

A door 60 is provided to the opening 54 in a freely openable/closable manner. The door 60 includes a locking unit 68. The locking unit 68 locks the door 60 to the main body 56 with the door 60 being closed, and cancels the locking when turned. When the door 60 with the canceled locking unit 68 is drawn to the exterior, the opening 54 can be opened. An internal seal 70 is provided between the door 60 and the main body 56. The door 60 air-tightly closes the opening 54 when fastened with the internal seal 70 being held between the door 60 and the main body 56. An external seal 62 is provided at the peripheral edge of the opening 54 of the main body 56.

In this embodiment, the wheels 64 are each a ball. The wheels 64 are provided at the four corners of the bottom of the main body 56, and travels on the carrying path 28 by rotational force given by an unillustrated drive unit. The control room 66 is provided on the bottom face of the main body 56, and retains a controller that controls the drive unit, a communication unit that communicates with the central control device and the chambers 18, and a power source which are not illustrated in the figure. The carrier unit 30 has an indicated ID (unillustrated) for identifying the carrier unit 30.

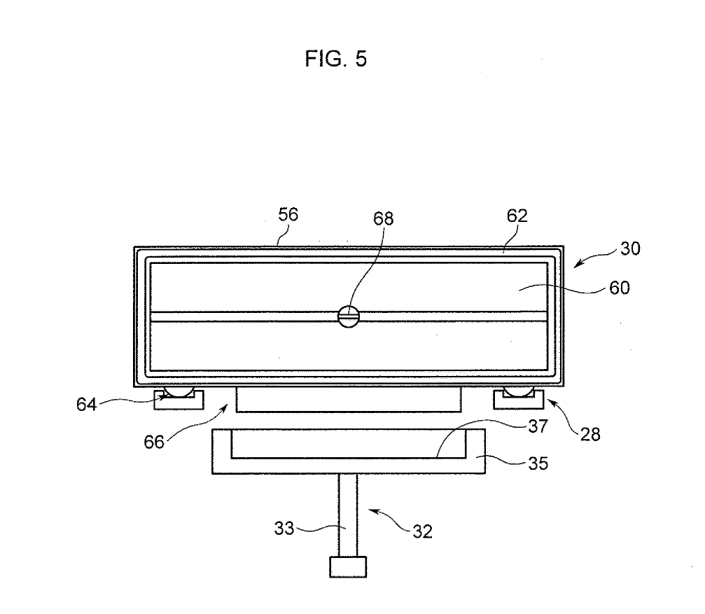

As illustrated in FIG. 5, the elevating unit 32 is disposed below the carrying path 28, and includes a telescopic support rod 33, a support table 35 that supports the carrier unit 30 from the bottom, and a moving mechanism (unillustrated) that moves the support table 35 back and forth with respect to the chamber 18. The elevating unit 32 lifts up the carrier unit 30 stopping ahead of the predetermined process unit 16, and rotates the supporting table 35. The supporting table 35 is provided with a recess 37 that does not interfere with the control room 66 of the carrier unit 30. The supporting table 35 is provided with a reader (unillustrated) that reads the ID of the carrier unit 30 provided at the bottom thereof.

### Operation and Advantageous Effect

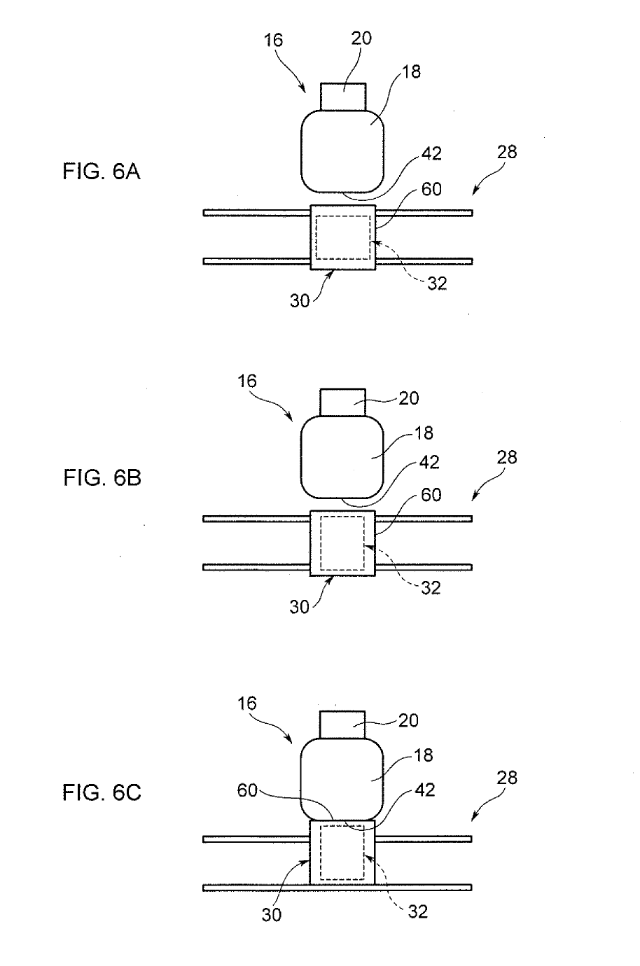

The semiconductor device manufacturing line 10 employing the above-explained structure has the central control device to give a carrying instruction to the carrier unit 30. This causes the carrier unit 30 to run on the carrying path 28 in accordance with the carrying instruction received from the central control device, and runs toward the predetermined process unit 16. When running on the carrying path 28, the carrier unit 30 runs with the door 60 being directed in the running direction. When confirming that the carrier unit 30 reaches a position ahead of the predetermined process unit 16, the carrier unit 30 stops at this position (see FIG. 6A). Next, the carrier unit 30 delivers the wafer W in synchronization with the chamber 18 without through the central control device. This operation will be explained below in more detail.

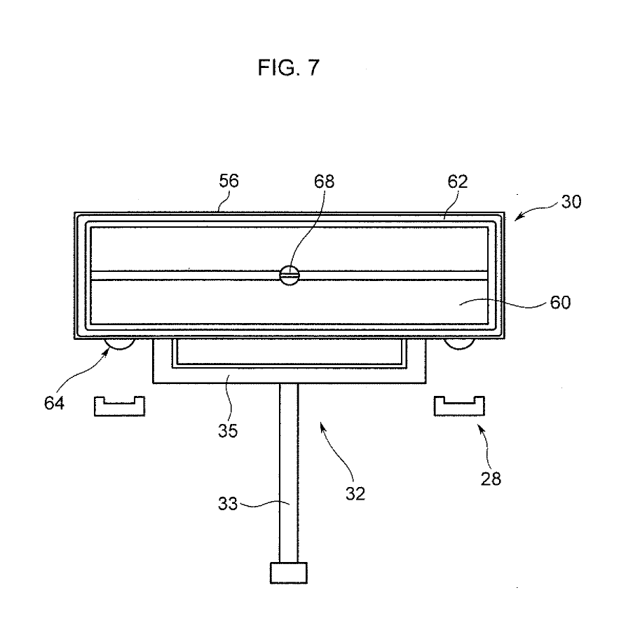

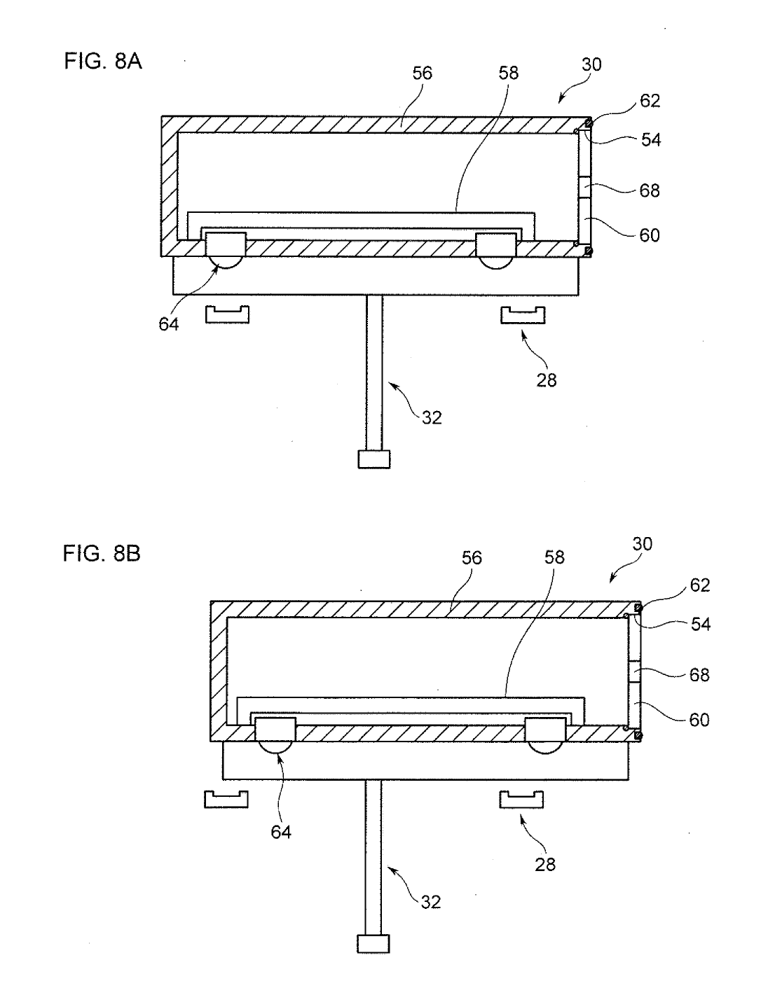

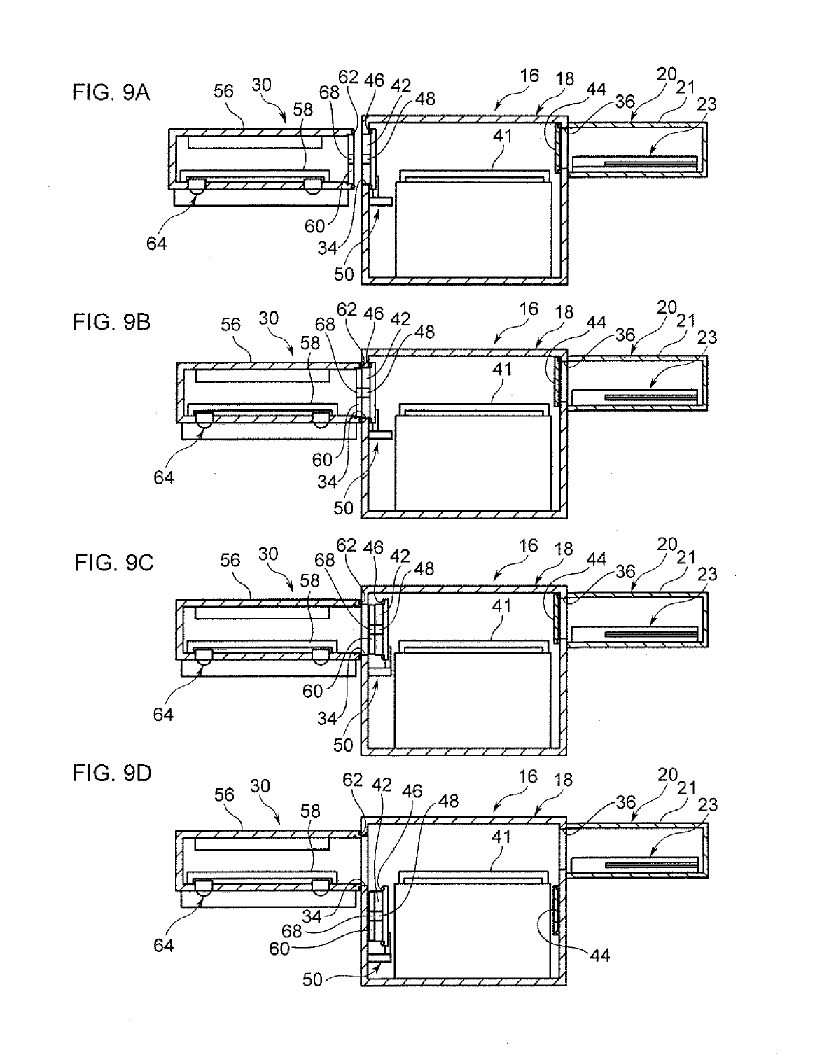

First, the elevating unit 32 reads the ID of the carrier unit 30 stopped ahead of the process unit 16, and thus the chamber 18 recognizes the ID of the carrier unit 30 through the elevating unit 32. This causes the elevating unit 32 to lift up the carrier unit 30 to a predetermined height while supporting the carrier unit 30 from the bottom (see FIG. 7). Next, the elevating unit 32 has the supporting table 35 rotated counterclockwise by 90 degrees to turn the carrier unit 30 (see FIG. 8A). Hence, the carrier unit 30 has the door 60 facing with the wafer door 42 of the chamber 18 (see FIGS. 6B and 9A). Next, the elevating unit 32 moves the carrier unit 30 forward toward the chamber 18 (see FIG. 8B). Hence, the carrier unit 30 has the door 60 contacting the wafer door 42 of the chamber 18 (see FIGS. 6C and 9B).

When confirming that the movement of the carrier unit 30 completes, the chamber 18 causes the suction unit (unillustrated) to suction gas in the closed space surrounded by the external seal 62 of the carrier unit 30 and the wafer door 42. Hence, the door 60 of the carrier unit 30 is suctioned, and the door 60 of the carrier unit 30 and the wafer door 42 are air-tightly joined together. Next, the chamber 18 cancels the locking by the locking unit 68 of the door 60 of the carrier unit 30, and draws the wafer door 42 joined with the door 60 of the carrier unit 30 in the main body 40 (see FIG. 9C). Subsequently, the chamber 18 moves the wafer door 42 joined with the door 60 of the carrier unit 30 downwardly, and opens the wafer opening 34 and the opening 54 of the carrier unit 30. Together with this operation, the arm door 44 is moved to open the arm opening 36 (see FIG. 9D).

Next, the arm 23 is elongated to pass through the wafer opening 34 and the opening 54 of the carrier unit 30, and receives the wafer W loaded in the carrier unit 30. The arm 23 is contracted and mounts the wafer W on the base 41 of the chamber 18, and is further contracted to retract in the arm room 21.

Next, the chamber 18 moves the wafer door 42 joined together with the door 60 of the carrier unit 30 to the height of the wafer opening 34 (see FIG. 9C). Subsequently, the wafer door 42 joined with the door 60 of the carrier unit 30 is pushed out toward the carrier unit 30, thereby blocking the wafer opening 34 and the opening 54 of the carrier unit 30. Together with this operation, the arm door 44 is moved to the arm opening 36, and the arm opening 36 is blocked (see FIG. 9B). Subsequently, the chamber 18 performs a predetermined process on the wafer W.

After the process completes, the chamber 18 moves the wafer door 42 joined with the door 60 of the carrier unit 30 and the arm door 44 through the same fashion as explained above to open the opening 54 of the carrier unit 30, the wafer opening 34, and the arm opening 36 (see FIG. 9D).

Next, the arm 23 is elongated, and receives the processed wafer W held on the base 41 of the chamber 18. The arm 23 is further elongated to pass through the wafer opening 34 and the opening 54 of the carrier unit 30, and mounts the wafer W on the base 58 in the carrier unit 30. The arm 23 is contracted to retract in the arm room 21.

Subsequently, the chamber 18 moves the wafer door 42 joined with the door 60 of the carrier unit 30 and the arm door 44 through the same fashion as explained above, and blocks off the opening 54 of the carrier unit 30, the wafer opening 34, and the arm opening 36 (see FIG. 9B).

The chamber 18 locks the locking unit 68 of the door 60 of the carrier unit 30, and cancels the suction operation. Hence, the joining of the door 60 with the wafer door 42 is released.

Next, the elevating unit 32 retracts the carrier unit 30 from the chamber 18 (see FIGS. 9A and 6B). Subsequently, the elevating unit 32 has the supporting table 35 rotated clockwise by 90 degrees to turn the carrier unit 30 in such a way that the door 60 directed in the running direction (see FIGS. 7 and 6A). The elevating unit 32 descends to place the wheels 64 on the carrying path 28 (see FIGS. 5 and 6A). Hence, the carrier unit 30 becomes able to run on the carrying path 28 toward the process unit 16 of the next process with the processed wafer W being retained in the carrier unit 30.

As explained above, the semiconductor device manufacturing line 10 causes the carrier unit 30 to run on the carrying path 28 to deliver one wafer W to each chamber 18 connected with the carrying path 28. That is, the semiconductor device manufacturing line 10 has a common carrier system 14, which allows each chamber 18 to be assembled in the manufacturing line only by connecting each chamber with the carrying path 28. Hence, the semiconductor device manufacturing line 10 facilitates an assembling of the manufacturing line using various chambers 18 of various device manufacturers.

Moreover, the process system 12 includes the simultaneous process unit 22 and the high-throughput process unit 24. This enables a setting of the tact times of the respective process units 16 to be the common target value. In the case of, for example, the chamber 18 having the throughput that is ½ of the target value of the tact time, by providing the simultaneous process unit 22 including the two chambers 18, the tact time can be adjusted to the target value. Moreover, in the case of the high-throughput process unit 24 having the throughput twice as much as the target value of the tact time, when such a process unit takes care of the two semiconductor device manufacturing lines, the tact time can be adjusted to the target value. This enables the semiconductor device manufacturing line 10 to deliver the wafers W simultaneously with respect to all process units 16. Hence, the semiconductor device manufacturing line 10 can reduce a waste time (or a waiting time) until a semiconductor device is finished. Note that a tact time is a time after the chamber 18 receives the wafer W from the carrier unit 30 and until the wafer W is delivered to the carrier unit 30.

The semiconductor device manufacturing line 10 causes the processed wafer W to stand by at the stand-by chamber 26, which further facilitates the adjustment of the tact time to the common target value.

The carrier unit 30 delivers the wafer W to the chamber 18 while maintaining the air-tightly closed condition, and thus it is not required to keep a high cleanness of the exterior of the chamber 18. Accordingly, it is necessary for the semiconductor device manufacturing line 10 to maintain the high cleanness of only the interior of the chamber 18 and the interior of the carrier unit 30. This can reduce the cleanness of the whole clean room.

The central control device sets the destination of the wafer W in the carrier unit 30 again when any defect occurs in the carrier unit 30 or the chamber 18, and performs a control of, for example, rescheduling the carriage of the wafer W after such an event or canceling the carriage of the wafer W. Accordingly, the semiconductor device manufacturing line 10 can smoothly carry the wafer W to the chamber 18 even if a defect occurs.

Furthermore, the central control device performs a dispatching of allocating a computing capacity and a carriage prediction control, thereby optimizing the carriage scheduling and the autonomous running of the carrier unit 30 in a real-time manner.

The semiconductor device manufacturing line 10 permits each chamber 18 to be assembled in the manufacturing line by only connecting such a chamber with the carrying path 28, and thus the semiconductor device manufacturing line 10 can easily cope with addition, deletion, and modification of the process.

### Modified Examples

The present invention is not limited to the above-explained embodiment, and can be changed and modified in various forms within the scope and spirit of the present invention.

In the above-explained embodiment, the explanation was given of an example case in which the semiconductor device manufacturing line 10 has the two manufacturing lines connected therewith through the high-throughput process unit, but the present invention is not limited to this case. For example, equal to or greater than three manufacturing lines can be connected.

The explanation was given of an example case in which the process system 12 is disposed at one side of the carrying path 28, but the present invention is not limited to this case. For example, the process system 12 may be disposed at both sides of the carrying path 28.

The explanation was given of an example ease in which the carrier system 14 has the carrier unit 30 autonomously running and moving toward the predetermined process unit, but the present invention is not limited to this case. The carrier unit may be moved to a predetermined process unit through the carrying path.

Although the explanation was given of an example case in which the carrier unit 30 has the wheels 64 rotated by rotational force by the drive unit and runs on the carrying path 28, the present invention is not limited to this case. The carrier unit 30 may run on the carrying path 28 by a combination of air-floating or magnetic-floating and thrust force.

The explanation was given of an example case in which the carrier unit 30 is formed of an air-tightly closed container, but the present invention is not limited to this case. The carrier unit 30 may be formed of a container open to atmosphere or maintaining a vacuum condition thereinside.

The explanation was given of an example case in which the carrying path 28 is formed by having the rails disposed horizontally, but the present invention is not limited to this case. The rails may be disposed in a manner inclined from the upstream side to the downstream side or vice versa.

Although the explanation was given of an example case in which the carrier system 14 has the elevating unit 32 that turns the carrier unit 30 toward the process unit 16, the present invention is not limited to this case. The turning operation of the carrier unit 30 may be omitted by carrying the carrier unit 30 with the opening 54 being directed to the process unit 16.

What is claimed is:

1. A semiconductor device manufacturing line comprising:
a process system comprising a plurality of process units of a single wafer process type; and
a carrier system that carries wafers to the plurality of process units;
wherein the carrier system comprises a plurality of carrier units each carrying one wafer from one of the process units to another process unit of a next process.

2. The semiconductor device manufacturing line according to claim 1, wherein the carrier unit comprises an air-tightly closed container.

3. The semiconductor device manufacturing line according to claim 1, wherein the carrier system comprises an elevating unit that moves the carrier unit to a height where the carrier unit can be coupled with the process unit.

4. The semiconductor device manufacturing line according to claim 1, wherein the plurality of carrier units deliver the wafers to the plurality of process units, respectively, at a same timing.

5. The semiconductor device manufacturing line according to claim 1, wherein the process unit comprises at least one chamber processing the wafer.

6. The semiconductor device manufacturing line according to claim 3, wherein the process system comprises a high-throughput process unit which receives the wafer from the process system of another semiconductor device manufacturing line provided in a parallel manner, and which returns the processed wafer to the another semiconductor device manufacturing line.
